(19) United States
(12) Patent Application Publication
(10) Pub. No.: US 2026/0247704 A1
(43) Pub. Date: Aug. 20, 2026

(54) SEMICONDUCTOR DEVICE AND METHOD OF MANUFACTURING THE SAME

(71) Applicant: Samsung Electronics Co., Ltd., Suwon-si (KR)

(72) Inventors: Seung Choi, Suwon-si (KR); Byungsung Kim, Suwon-si (KR); Junghan Lee, Suwon-si (KR)

(21) Appl. No.: 19/296,574

(22) Filed: Aug. 11, 2025

(30) Foreign Application Priority Data
Feb. 20, 2025 (KR) 10-2025-0022223

(51) Int. Cl. H10D 84/85; H10D 84/01

(52) U.S. Cl. CPC H10D 84/851; H10D 84/0167; H10D 84/017; H10D 84/0186; H10D 84/0188

(57) ABSTRACT

An example semiconductor device includes a substrate insulating layer; an insulating structure penetrating the substrate insulating layer; a first transistor on one side of the insulating structure; a second transistor on one side opposing the one side of the insulating structure; and dummy gate structures between the first transistor and the insulating structure and between the second transistor and the insulating structure, wherein the insulating structure includes a lower insulating pattern penetrating the substrate insulating layer; and an upper insulating liner covering at least a portion of side surfaces, opposing each other, of the dummy gate structures, and wherein the lower insulating pattern including a material having a dielectric constant different from a dielectric constant of the substrate insulating layer.

### CROSS-REFERENCE TO RELATED APPLICATION

This application claims the benefit of priority to Korean Patent Application No. 10-2025-0022223 filed on Feb. 20, 2025 in the Korean Intellectual Property Office, the disclosure of which is incorporated herein by reference in its entirety.

### BACKGROUND

As demand for high performance, high speed, and/or multifunctionality of a semiconductor device has increased, integration density of a semiconductor device has increased. In accordance with the trend toward high integration density of a semiconductor device, a semiconductor device having a backside power delivery network (BSPDN) structure in which a power rail is disposed on a back surface of a wafer has been developed. Also, to overcome limitations of operating properties due to reduction of a size of a metal oxide semiconductor FET (planar MOSFET), efforts have been made to develop a semiconductor device including a FinFET including a three-dimensional structure channel and a method of manufacturing the same.

### SUMMARY

The present disclosure relates to a semiconductor device having improved integration density and reliability, and a method of manufacturing a semiconductor device having improved integration density and reliability.

In general, according to some aspects, a semiconductor device includes a substrate insulating layer; an insulating structure penetrating the substrate insulating layer; a first transistor on one side of the insulating structure, and including a first gate structure extending in one direction on the substrate insulating layer, and first source/drain regions having a first conductivity-type on both sides of the first gate structure; a second transistor on one side opposing the one side of the insulating structure, and including a second gate structure extending in the one direction on the substrate insulating layer, and second source/drain regions having a second conductivity-type different from the first conductivity-type on both sides of the second gate structure; dummy gate structures between the first transistor and the insulating structure and between the second transistor and the insulating structure, wherein the insulating structure includes a lower insulating pattern penetrating the substrate insulating layer; and an upper insulating liner covering at least a portion of side surfaces, opposing each other, of the dummy gate structures, and wherein the lower insulating pattern includes a material having a dielectric constant different from a dielectric constant of the substrate insulating layer.

In general, according to some aspects, a semiconductor device includes a substrate insulating layer; gate structures spaced apart from each other in a first direction on the substrate insulating layer and extending in a second direction intersecting the first direction; a plurality of channel layers surrounded by the gate structures on the substrate insulating layer, respectively; an upper insulating liner covering side surfaces, opposing each other, of the gate structures on the substrate insulating layer; a lower insulating pattern penetrating the substrate insulating layer and in contact with the upper insulating liner; source/drain regions on an external side of the gate structures and connected to the plurality of channel layers; and backside contact structures penetrating the substrate insulating layer and connected to the source/drain regions, wherein the upper insulating liner includes a lower portion in contact with the substrate insulating layer and the lower insulating pattern, and side portions extending along the side surfaces, opposing each other, of the gate structures.

In general, according to some aspects, a semiconductor device includes a substrate insulating layer; a plurality of gate structures spaced apart from each other in a first direction on the substrate insulating layer, and extending in a second direction intersecting the first direction, wherein the plurality of gate structures include a first gate structure, a second gate structure, and dummy gate structures between the first gate structure and the second gate structure; first source/drain regions on both sides of the first gate structure; second source/drain regions on both sides of the second gate structure; and an insulating structure between the dummy gate structures, wherein the insulating structure further includes an upper insulating layer between the dummy gate structures on the substrate insulating layer; an insulating liner extending in the second direction between the upper insulating layer and the dummy gate structures; and a lower insulating pattern penetrating the substrate insulating layer and in contact with the insulating liner.

### BRIEF DESCRIPTION OF THE DRAWINGS

The above and other aspects, features, and advantages of the present disclosure will be more clearly understood from the following detailed description, taken in combination with the accompanying drawings.

FIG. 1A is a plan diagram illustrating an example of a semiconductor device.

FIG. 1B is cross-sectional diagrams illustrating an example of a semiconductor device.

FIG. 1C is cross-sectional diagrams illustrating an example of a semiconductor device.

FIGS. 2, 3, 4, 5, 6, 7, and 8 are cross-sectional diagrams illustrating an example of a semiconductor device.

FIGS. 9A, 9B, 9C, 9D, 9E, 9F, 9G, 9H, 9I, 9J, 9K, 9L, 9M, 9N, 9O, 9P, 9Q, 9R, 9S, and 9T are cross-sectional diagrams illustrating processes of an example of a method of manufacturing a semiconductor device in order.

FIGS. 10A and 10B are cross-sectional diagrams illustrating processes of an example of a method of manufacturing a semiconductor device in order.

FIGS. 11A, 11B, 11C, and 11D are cross-sectional diagrams illustrating processes of an example of a method of manufacturing a semiconductor device in order.

FIGS. 12A, 12B, 12C, 12D, and 12E are cross-sectional diagrams illustrating processes of an example of a method of manufacturing a semiconductor device in order.

### DETAILED DESCRIPTION

Hereinafter, implementations of the present disclosure will be described as below with reference to the accompanying drawings.

In example implementations, the terms such as “upper,” “upper portion,” “upper surface,” “lower,” “lower portion,” “lower surface,” “side surface,” or the like, are based on the drawings unless otherwise indicated.

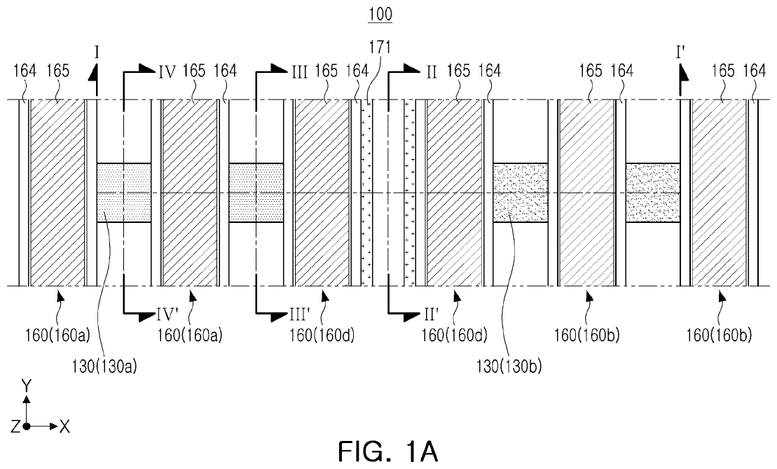

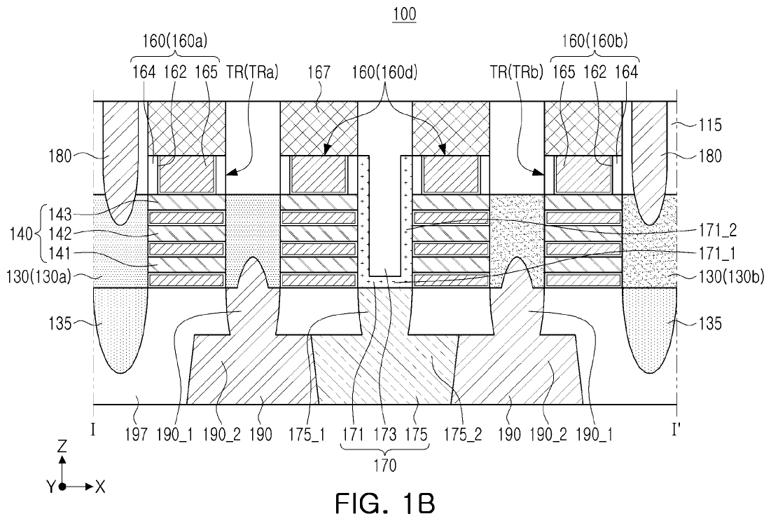

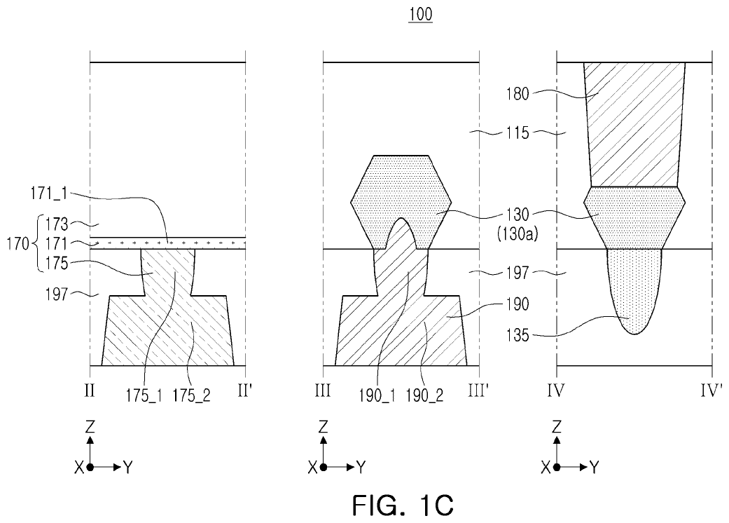

FIG. 1A is a plan diagram illustrating an example of a semiconductor device. For ease of description, FIG. 1 illustrates a portion of components of the semiconductor device.

FIG. 1B is cross-sectional diagrams illustrating an example of a semiconductor device, taken along lines I-I′ in FIG. 1A.

FIG. 1C is cross-sectional diagrams illustrating an example of a semiconductor device, taken along lines II-II′, III-III′ and IV-IV′.

Referring to FIGS. 1A to 1C, a semiconductor device 100 may include a substrate insulating layer 197, gate structures 160 extending in one direction on the substrate insulating layer 194 and including gate electrodes 165, channel structures 140 including first to third channel layers 141, 142, and 143 spaced apart from each other vertically on the substrate insulating layer 197, source/drain regions 130 in contact with the channel structures 140, front-side contact structures 180 penetrating the interlayer insulating layer 115 and connected to the source/drain regions 130, and backside contact structures 190 penetrating the substrate insulating layer 197 and connected to the source/drain regions 130. The semiconductor device 100 may include a first transistor TRa, a second transistor TRb, and an insulating structure 170 disposed therebetween.

In the semiconductor device 100, the gate electrode 165 may be disposed between the substrate insulating layer 197 and the channel structure 140, between the first to third channel layers 141, 142, and 143 of the channel structure 140, and on the channel structure 140. Accordingly, the semiconductor device 100 may include transistors TR having a multibridge channel (MBCFET™) structure, which is a gate-all-around field effect transistor.

The first transistor TRa and the second transistor TRb may be disposed on both sides of the insulating structure 170. The first transistor TRa may include a first gate structure 160a and first source/drain regions 130a of a first conductivity-type. The first transistor TRa may further include a first front-side contact structure 180 and a first backside contact structure 190. The second transistor TRb may include a second gate structure 160b and second source/drain regions 130b of a second conductivity-type. The second transistor TRb may further include a second front-side contact structure 180 and a second backside contact structure 190. In some implementations, by including the insulating structure 170 disposed between the first transistor TRa and the second transistor TRb of different conductivity types, disposed adjacently, space loss between the first transistor TRa and the second transistor TRb may be reduced, and the semiconductor device having improved integration density and reliability may be provided.

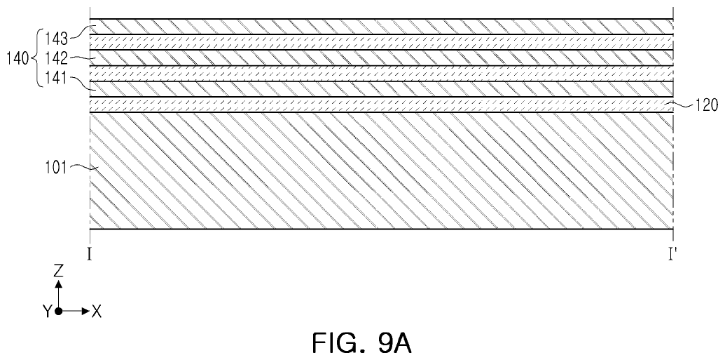

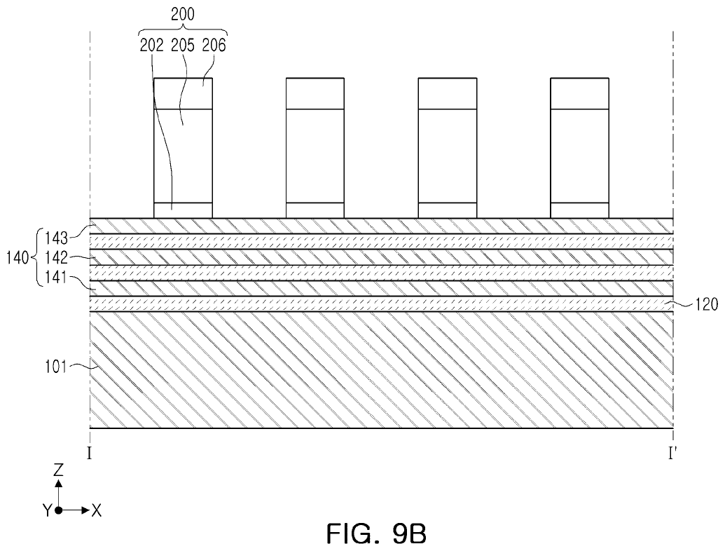

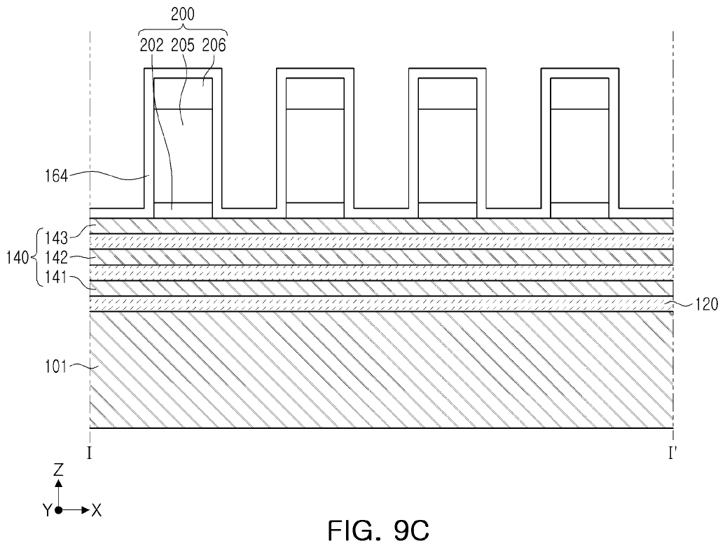

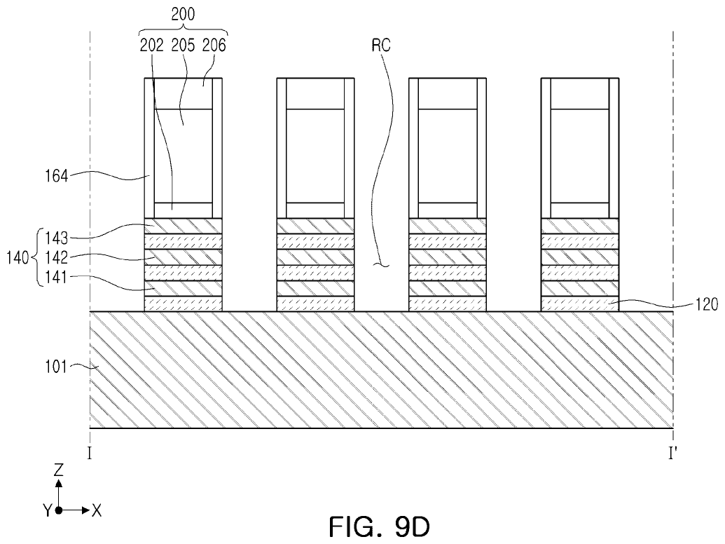

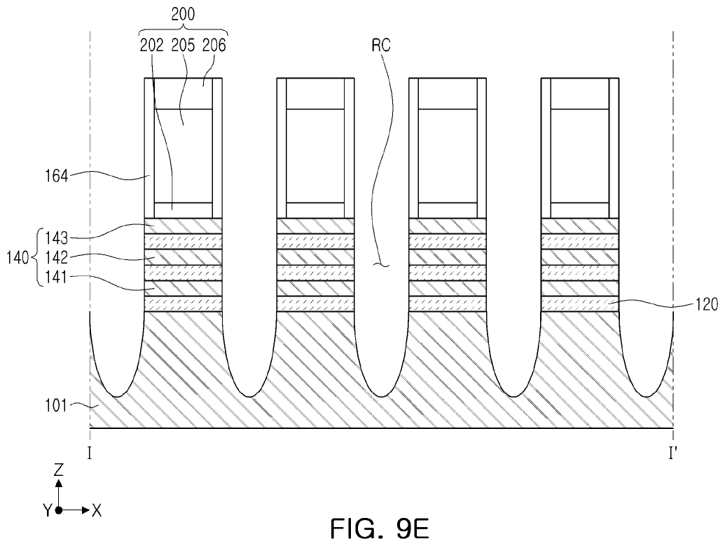

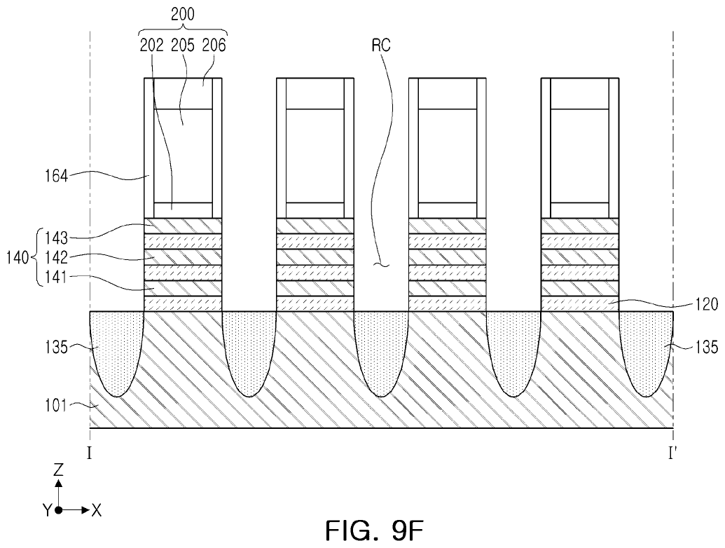

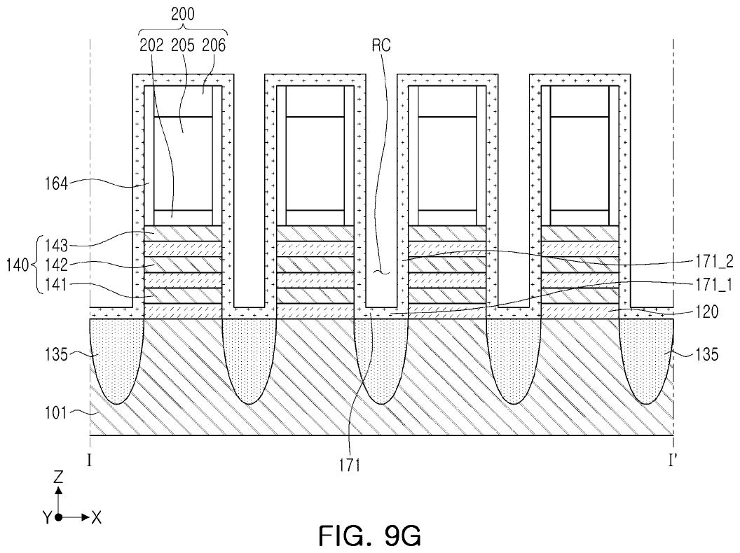

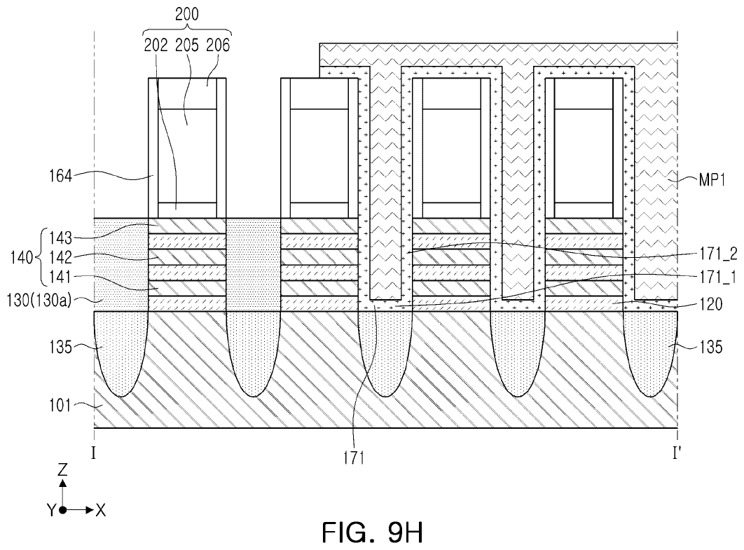

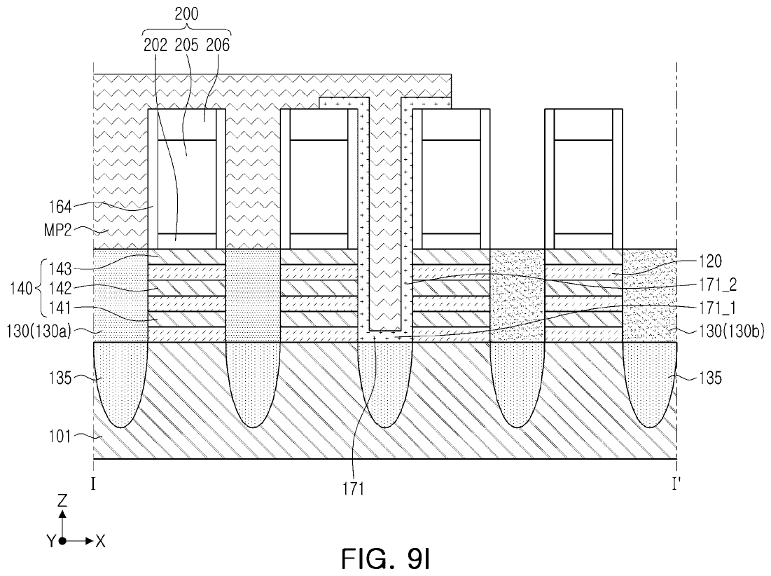

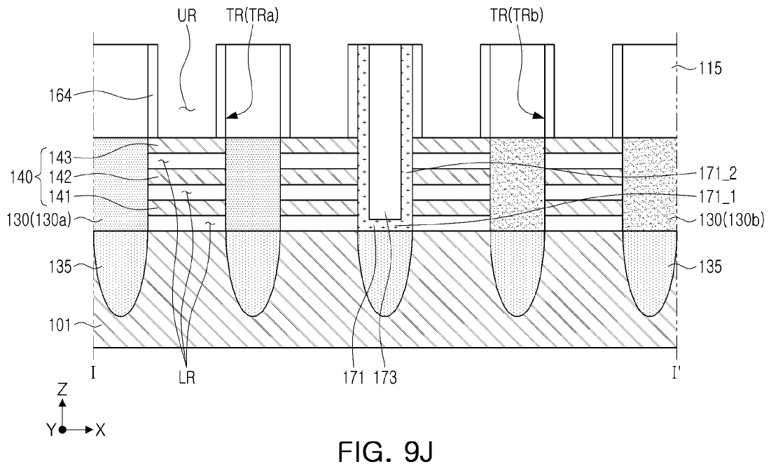

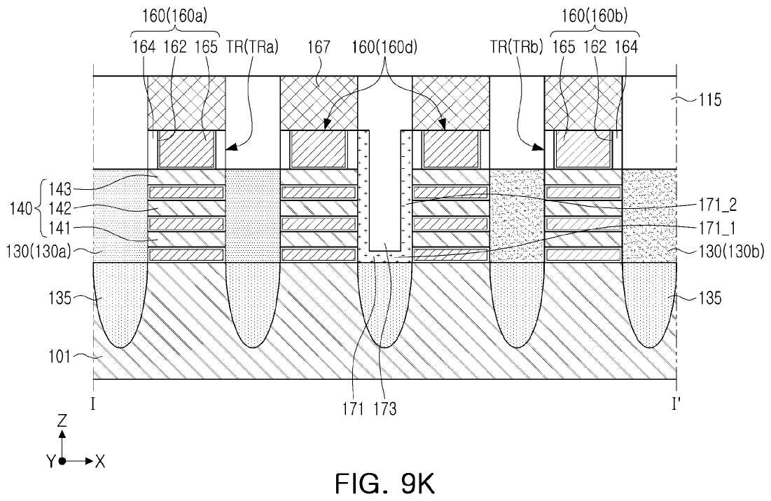

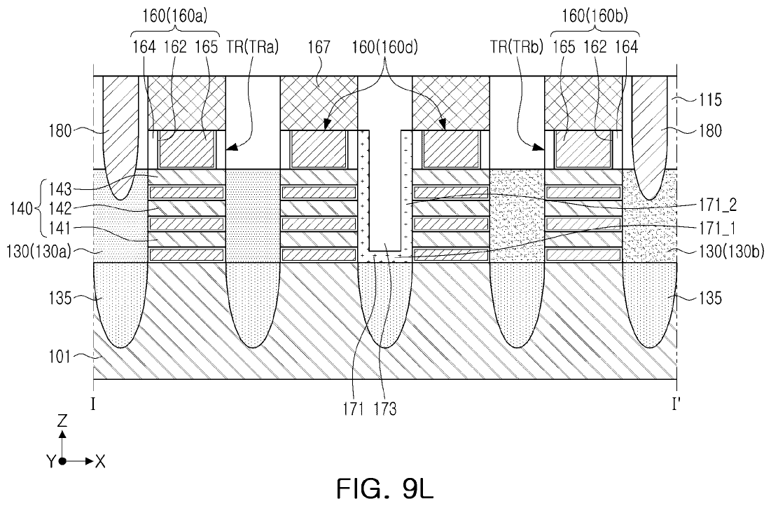

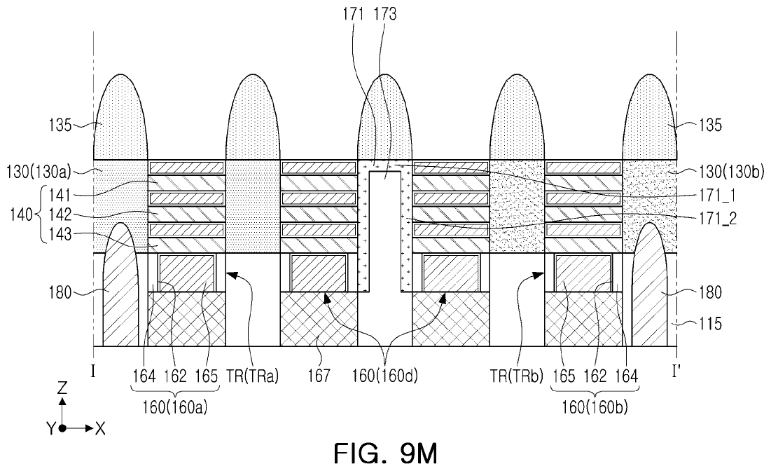

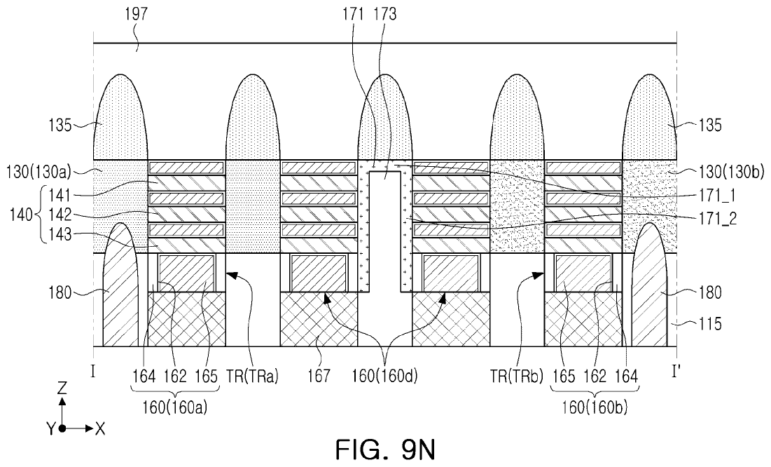

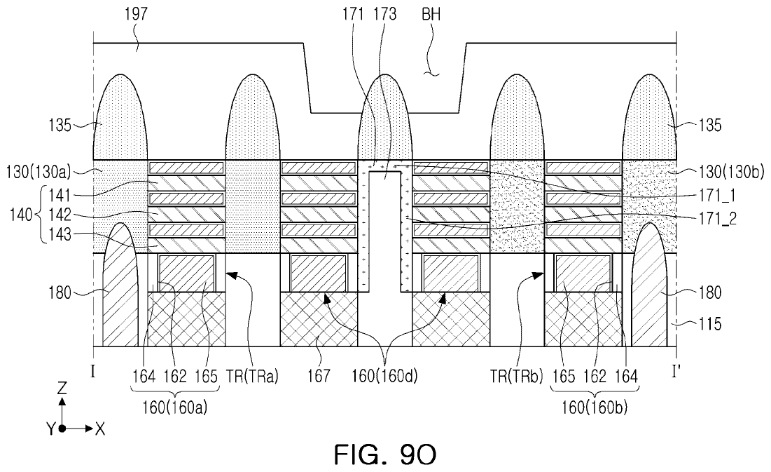

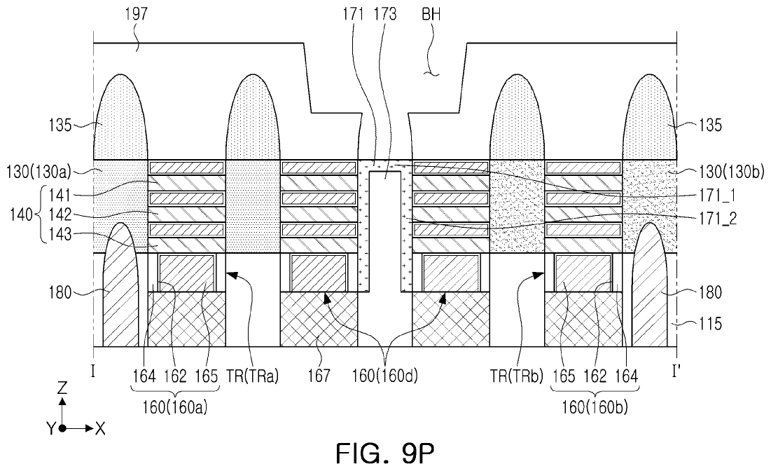

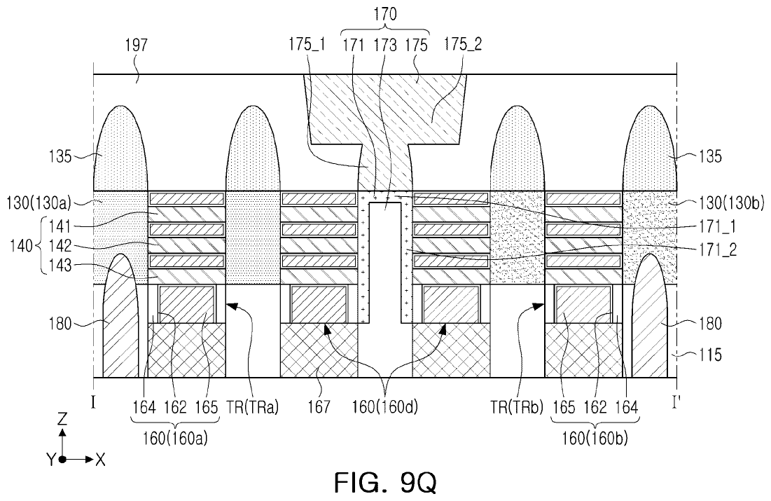

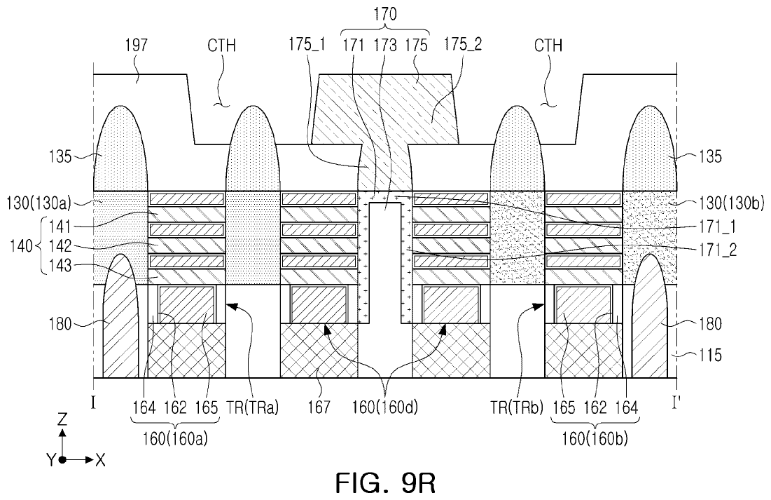

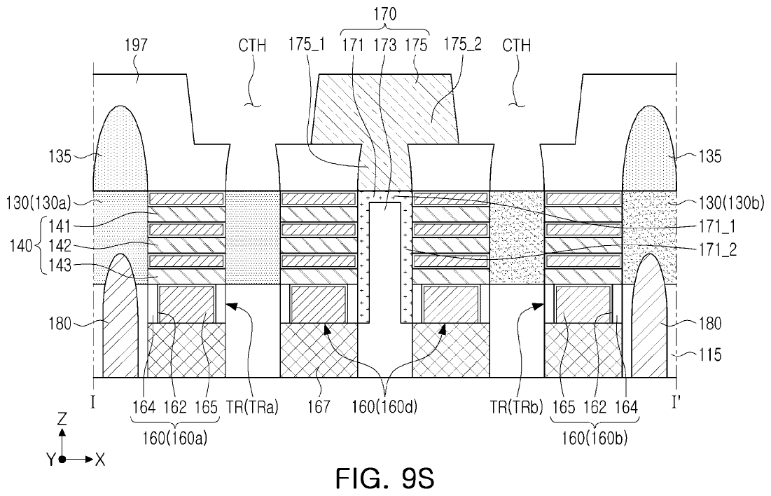

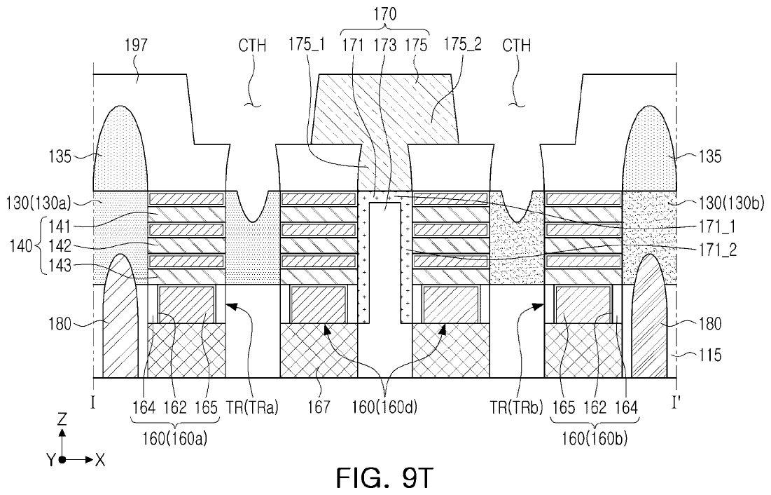

The substrate insulating layer 197 may have an upper surface extending in the X-direction and the Y-direction. The substrate insulating layer 197 may be formed by removing and/or oxidizing a substrate 101 (see FIG. 9A) formed of a semiconductor material during a manufacturing process. The substrate insulating layer 197 may be formed of an insulating material, and may include, for example, an oxide, a nitride, or a combination thereof. In some implementations, the substrate insulating layer 197 may include a low-κ material. In some implementations, the substrate insulating layer 197 may include a plurality of insulating layers.

The channel structures 140 may be disposed on the substrate insulating layer 194 to intersect the gate structures 160. Each of the channel structures 140 may include first to third channel layers 141, 142, and 143, which are two or more of a plurality of channel layers spaced apart from each other in the Z-direction. The channel structures 140 may be connected to the source/drain regions 130. The channel structures 140 may have a width the same as or similar to a width of the gate structures 160 widths in the X-direction. In some implementations, in a cross-sectional surface in the Y-direction, a channel layer disposed in a lower portion of the first to third channel layers 141, 142, and 143 may have a width the same as or greater than a width of a channel layer disposed in an upper portion. In some implementations, the channel structures 140 may have a reduced width as compared to the gate structures 160 such that side surfaces thereof are positioned below the gate structures 160 in the X-direction.

The channel structures 140 may be formed of a semiconductor material, and may include at least one of silicon (Si), silicon germanium (SiGe), and germanium (Ge). The number of the channel layers included in the channel structure 140 and the shape thereof may be varied in some implementations.

The gate structures 160 may be disposed to extend in one direction, for example, the Y-direction, on the substrate insulating layer 197. Channel regions of transistors may be formed in the channel structures 140 intersecting the gate electrodes 165 of the gate structures 160. The gate structures 160 may be spaced apart from each other in the X-direction. The gate structures 160 may include a first gate structure 160a included in a first transistor TRa, a second gate structure 160b included in a second transistor TRb, and dummy gate structures 160d disposed adjacently to the insulating structures 170. Dummy gate structures 160d may not be included in the first transistor TRa and the second transistor TRb and may be dummy components to which no electrical signal is applied.

Each of gate structures 160 may include gate dielectric layers 162, gate spacer layers 164, and a gate electrode 165. In some implementations, each of the gate structures 160 may further include a gate capping layer 167 on an upper surface of the gate electrode 165.

The gate dielectric layers 162 may be disposed between the substrate insulating layer 194 and the gate electrode 165 and between the channel structure 140 and the gate electrode 165, and may be disposed to cover at least a portion of surfaces of the gate electrode 165. For example, the gate dielectric layers 162 may be disposed to surround overall surfaces other than an uppermost surface of the gate electrode 165. The gate dielectric layers 162 may extend between the gate electrode 165 and the gate spacer layers 164, but an example implementation thereof is not limited thereto. The gate dielectric layers 162 may include an oxide, a nitride, or a high-κ material. The high-κ material may refer to a dielectric material having a dielectric constant higher than that of a silicon oxide film (SiO₂). The high-κ material may be, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃). In some implementations, the gate dielectric layers 162 may have a multilayer structure.

The gate electrode 165 may include a conductive material, for example, a metal nitride such as titanium nitride (TiN), tantalum nitride (TaN), or tungsten nitride (WN), and/or a metal material such as aluminum (Al), tungsten (W), or molybdenum (Mo), or a semiconductor material such as doped polysilicon. In some implementations, the gate electrode 165 may have a multilayer structure. In a region not illustrated, the gate electrodes 165 may be connected to upper contact structures disposed thereon.

Gate spacer layers 164 may be disposed on both side surfaces of the gate electrode 165 on the channel structure 140. The gate spacer layers 164 may insulate the source/drain regions 130 and the gate electrodes 165 from each other. In some implementations, a shape of an upper end of the gate spacer layers 164 may be varied, and the gate spacer layers 164 may have a multilayer structure. The gate spacer layers 164 may include at least one of an oxide, a nitride, and an oxynitride, and may be formed of, for example, a low-κ film.

The source/drain regions 130 may be disposed to be in contact with the channel structures 140 on at least one side of the gate structures 160. The source/drain regions 130 may be connected to the channel structures 140. The source/drain regions 130 may be disposed to cover side surfaces in the X-direction of each of the first to third channel layers 141, 142, and 143 of the channel structures 140. An upper surface of the source/drain region 130 may be positioned at a level the same as or similar to a level of a lower surface of the gate electrode 165 on the uppermost channel layer 143, the level may be varied in some implementations. The source/drain region 130 may not be disposed between the dummy gate structures 160d in which the insulating structure 170 is disposed.

The specific shape of side surfaces of the source/drain regions 130 may be varied in some implementations. The source/drain regions 130 may be an epitaxially grown region and may include a plurality of epitaxial layers. The epitaxially grown surfaces of the source/drain regions 130 may be in contact with the channel structures 140 and the interlayer insulating layer 115.

The source/drain regions 130 may include first source/drain regions 130a included in the first transistor TRa and second source/drain regions 130b included in the second transistor TRb. The first source/drain region 130a may have a first conductivity-type and may be included in the first transistor TRa of the first conductivity-type, and the second source/drain region 130b may have a second conductivity-type and may be included in the second transistor TRb of the second conductivity-type.

The source/drain regions 130 may include at least one of a semiconductor material, for example, silicon (Si) and germanium (Ge), and may further include dopants. For example, when the first conductivity-type of the first transistor TRa is P-type, the first transistor TRa may be a pFET, and the dopants included in the first source/drain regions 130a may be at least one of boron (B), gallium (Ga), or indium (In). The first source/drain regions 130a, which are P-type, may include silicon germanium (SiGe). Also, when the second conductivity-type of the second transistor TRb is N-type, the second transistor TRb may be an nFET, and the dopants included in the second source/drain regions 130b may be at least one of phosphorus (P), arsenic (As), or antimony (Sb). The second source/drain regions 130b, which are N-type, may include silicon (Si).

The molding layer 135 may be disposed below the source/drain region 130 not connected to the backside contact structure 190. The molding layer 135 may be a component used to form the lower insulating pattern 175 and the backside contact structure 190. The molding layer 135 may be removed from a region in which the backside contact structure 190 is to be formed, and may not be disposed below the source/drain region 130 connected to the backside contact structure 190. The molding layer 135 may include at least one of silicon (Si) and germanium (Ge), and in some implementations, the molding layer 135 may include silicon germanium (SiGe) having a composition different from a composition of the source/drain region 130. For example, the molding layer 135 may have a germanium (Ge) concentration higher than a germanium (Ge) concentration of the first source/drain regions 130a which is P-type.

The insulating structure 170 may be disposed between the gate structures 160. The insulating structure 170 may be disposed between the first transistor TRa and the second transistor TRb adjacent to each other, and between the dummy gate structures 160d not included in the first transistor TRa and the second transistor TRb. The insulating structure 170 may include an upper insulating liner 171, an upper insulating layer 173, and a lower insulating pattern 175.

The upper insulating liner 171 may cover a side surface of the adjacent gate structures 160 on the substrate insulating layer 197. The upper insulating liner 171 may cover at least a portion of side surfaces of the dummy gate structures 160d, opposing each other. The first transistor TRa and the second transistor TRb may be spaced apart from each other in the first direction (e.g., X-direction), and the upper insulating liner 171 may extend in the second direction (e.g., Y-direction) along which the gate structures 160 extend. The upper insulating liner 171 may include a lower portion 171_1 covering an upper surface of a substrate insulating layer 197 and an upper surface of a lower insulating pattern 175 and extending in the second direction, and side portions 171_2 covering side surfaces of adjacent gate structures 160 and extending in the second direction. The upper insulating liner 171 including the lower portion 171_1 and the side portions 171_2 may have a “U” shape in a cross-sectional surface in the first direction. The side portions 171_2 of the upper insulating liner 171 may be in contact with the plurality of channel layers 141, 142, and 143, surrounded by the dummy gate structures 160d. An upper end of the upper insulating liner 171 may be positioned at the same level as a level of an upper surface of the gate electrode 165, that is, an upper surface of the gate structure 160d. In some implementations, differently from the illustrated example, the upper insulating liner 171 may be formed to fill a space between adjacent dummy gate structures 160d. The upper insulating liner 171 may include an insulating material, and may include a material different from a material of the lower insulating pattern 175. The upper insulating liner 171 may include, for example, silicon nitride, such as SiN, SiOCN, or SiCN.

The upper insulating layer 173 may be disposed on the upper insulating liner 171. The upper insulating layer 173 may fill a space between the dummy gate structures 160d on the upper insulating liner 171. The upper insulating layer 173 may include the same material as the interlayer insulating layer 115 and may be a component formed by the same process. Depending on the method of description, the upper insulating layer 173 may be described as a component included in the interlayer insulating layer 115, and the upper insulating layer 173 may be a portion disposed between the dummy gate structures 160d of the interlayer insulating layer 115. In some implementations, differently from the illustrated example, when the upper insulating liner 171 is formed to fill a space between adjacent dummy gate structures 160d, the upper insulating layer 173 may be not included or may be formed in a region smaller than the illustrated example. The upper insulating layer 173 may include an insulating material and may include a material different from a material the upper insulating liner 171. The upper insulating layer 173 may include, for example, silicon oxide such as SiO or a low-κ material.

The lower insulating pattern 175 may penetrate the substrate insulating layer 197 and may be in contact with the upper insulating liner 171. Differently from the example in which the upper insulating liner 171 extends in the second direction, the lower insulating pattern 175 may have a via shape penetrating the substrate insulating layer 197. The lower insulating pattern 175 may be in contact with the backside contact structures 190. The lower insulating pattern 175 may include a first pattern portion 175_1 in contact with the upper insulating liner 171 and a second pattern portion 175_2 having a width greater than a width of the first pattern portion 175_1 below the first pattern portion 175_1. The lower insulating pattern 175 may have a step difference between the first pattern portion 175_1 and the second pattern portion 175_2. The first pattern portion 175_1 may include a portion of which a width decreases as the level decreases. The second pattern portion 175_2 may be in contact with the adjacent backside contact structure 190. The lower insulating pattern 175 may include an insulating material and may include a material having a dielectric constant different from a dielectric constant of the substrate insulating layer 197. The lower insulating pattern 175 may include a material having a dielectric constant lower than a dielectric constant of the substrate insulating layer 197. The lower insulating pattern 175 may include a low-κ material. The lower insulating pattern 175 may include, for example, silicon carbon oxide such as SiC or SiOC. By including a low-κ material in the lower insulating pattern 175 disposed between the backside contact structures 190, performance of the adjacent first transistor TRa and second transistor TRb may be improved.

The insulating structure 170 may be a component required to form the adjacent first transistor TRa and second transistor TRb having different conductivity types. For example, the first source/drain regions 130a of the first conductivity-type may be formed in a separate process from the second source/drain regions 130b of the second conductivity-type, and a space may be required to ensure a margin therebetween. In some implementations, by including the insulating structure 170, a manufacturing method having improved integration density and reliability may be provided, and a description thereof will be provided later in relation to the description of the manufacturing method.

The front-side contact structure 180 may penetrate the interlayer insulating layer 115, may be connected to a portion of the source/drain regions 130, and may apply an electrical signal to the connected source/drain region 130. In some implementations, the front-side contact structure 180 may be connected to a source/drain region 130 to which a backside contact structure 190 is not connected. In some implementations, the front-side contact structure 180 may be connected to a source/drain region 130 relatively spaced apart from the insulating structure 170 among the source/drain regions 130 included in the transistor TR. The front-side contact structure 180 included in the first transistor TRa may be referred to as the first front-side contact structure 180, and the front-side contact structure 180 included in the second transistor TRb may be referred to as the second front-side contact structure 180. The front-side contact structure 180 may be recessed into the connected source/drain region 130 from an upper surface and may extend into the source/drain region 130. In some implementations, the front-side contact structure 180 may extend below a lower surface of an uppermost channel layer 143. In some implementations, the front-side contact structure 180 may extend from an upper portion below a lower surface of a second channel layer 142. At least a portion of a side surface of the front-side contact structure 180 may be inclined such that a width of the front-side contact structure 180 may decrease as the level decreases. The front-side contact structure 180 may include a metal material such as, for example, tungsten (W), cobalt (Co), molybdenum (Mo), copper (Cu), ruthenium (Ru), or aluminum (Al). The front-side contact structure 180 may include a metal nitride, such as titanium nitride (TiN), tantalum nitride (TaN), or tungsten nitride (WN), or may include a metal, such as titanium (Ti), cobalt (Co), molybdenum (Mo), or platinum (Pt). In some implementations, the front-side contact structure 180 may include a metal-semiconductor compound layer, such as a metal silicide layer, disposed at an interfacial surface in contact with the source/drain region 130.

The backside contact structure 190 may penetrate the substrate insulating layer 197 and may be connected to the source/drain region 130. In some implementations, the backside contact structure 190 may be connected to a source/drain region 130 adjacent to an insulating structure 170 among the source/drain regions 130 included in the transistor TR. The backside contact structure 190 included in the first transistor TRa may be referred to as the first backside contact structure 190, and the backside contact structure 190 included in the second transistor TRb may be referred to as the second backside contact structure 190. The backside contact structure 190 may be partially recessed into the source/drain region 130 from an upper surface and may extend into the source/drain region 130. In some implementations, the backside contact structure 190 may extend above a lower surface of the lowermost channel layer 141. In some implementations, the backside contact structure 190 may extend above an upper surface of the lowermost channel layer 141. The backside contact structure 190 may include a first contact portion 190_1 connected to the source/drain region 130 and a second contact portion 190_2 having a width greater than a width of the first contact portion 190_1 below the first contact portion 190_1. The backside contact structure 190 may have a step difference between the first contact portion 190_1 and the second contact portion 190_2. The first contact portion 190_1 may include a portion of which a width decreases as the level decreases. The second contact portion 190_2 may be in contact with the lower insulating pattern 175. At least a portion of a side surface of the backside contact structure 190 may be inclined such that a width of the backside contact structure 190 may increase as the level decreases. The backside contact structure 190 may include a metal material, such as, for example, tungsten (W), cobalt (Co), molybdenum (Mo), copper (Cu), ruthenium (Ru), or aluminum (Al). The backside contact structure 190 may include a metal nitride, such as, for example, titanium nitride (TiN), tantalum nitride (TaN), or tungsten nitride (WN), or a metal, such as titanium (Ti), cobalt (Co), molybdenum (Mo), or platinum (Pt). In some implementations, the backside contact structure 190 may include a metal-semiconductor compound layer, such as a metal silicide layer, disposed on an interfacial surface in contact with the source/drain region 130.

The gate contact structure and the front interconnection structure such as the contact structures 180 and 190 may be disposed on the gate electrode 165 of the first gate structure 160a and the gate electrode 165 of the second gate structure 160b, and the interconnection structure such as the interconnection line connected to the front-side contact structure 180 may be disposed on the front-side contact structure 180. The gate contact structure may not be disposed on the gate electrode 165 of the dummy gate structure 160d, and the dummy gate structure 160d may not be connected to the front interconnection structure. A lower interconnection structure that applies power or a ground voltage to the backside contact structure 190 may be disposed below the backside contact structure 190, may form a BSPDN, and may be referred to as a backside power rail or a buried power rail.

The semiconductor device 100 may be packaged such that the structure in FIG. 1B may be disposed upside down such that such that the backside contact structure 190 may be positioned on an upper portion, but the packaging form of the semiconductor device 100 is not limited thereto.

In the description of the example implementations below, the description overlapping the description described above with reference to FIGS. 1A to 1C will not be provided.

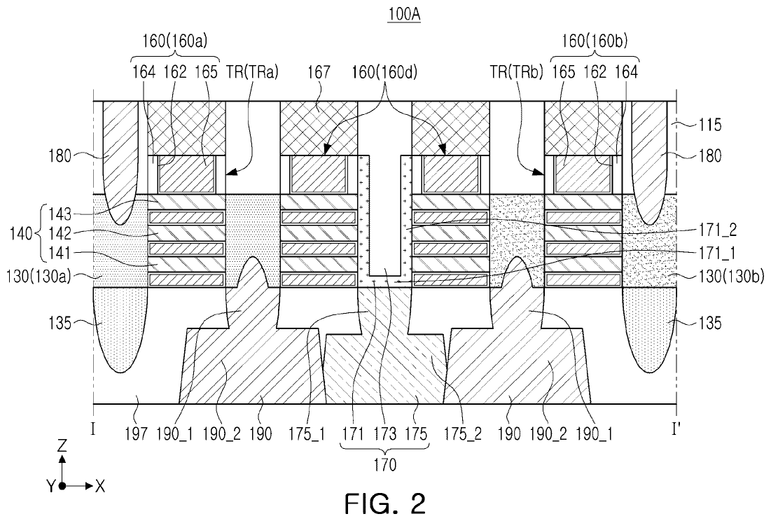

FIGS. 2, 3, 4, 5, 6, 7, and 8 are cross-sectional diagrams illustrating an example of a semiconductor device, illustrating regions corresponding to FIG. 1B.

Referring to FIG. 2, differently from the semiconductor device 100 in FIG. 1B, the semiconductor device 100a may include a portion of the second pattern portion 175_2 of the lower insulating pattern 175 of which a width increases as the level decreases, and a portion in contact with the second contact portion 190_2 of the backside contact structure 190 and of which a width decreases as the level decreases. A side surface of the portion of the second pattern portion 175_2 of which a width decreases as the level decreases may be a side surface formed along a shape of a side surface of the second contact portion 190_2. In some implementations, the backside contact structure 190 may be formed after the lower insulating pattern 175 may be formed preferentially, and depending on a position and a size of the contact hole forming the backside contact structure 190, a contact form with the lower insulating pattern 175, and a shape of the second pattern portion 175_2 may vary. Levels of an upper surface of the second pattern portion 175_2 and an upper surface of the second contact portion 190_2 may be different from each other. In some implementations, as illustrated, an upper surface of the second pattern portion 175_2 may be positioned at a lower level than a level of an upper surface of the second contact portion 190_2. In some implementations, differently from illustrated, an upper surface of the second pattern portion 175_2 may be positioned at a level lower than a level of an upper surface of the second pattern portion 175_2.

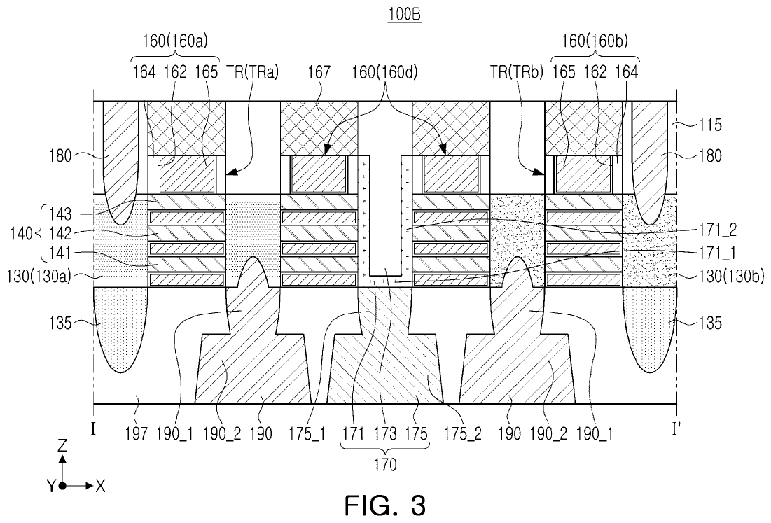

Referring to FIG. 3, differently from the semiconductor device 100 in FIG. 1B, in a semiconductor device 100b, the lower insulating pattern 175 and the backside contact structure 190 may be spaced apart from each other. The first pattern portion 175_1 of the lower insulating pattern 175 and the first contact portion 190_1 of the backside contact structure 190 may be spaced apart from each other, and also the second pattern portion 175_2 and the second contact portion 190_2 may be spaced apart from each other.

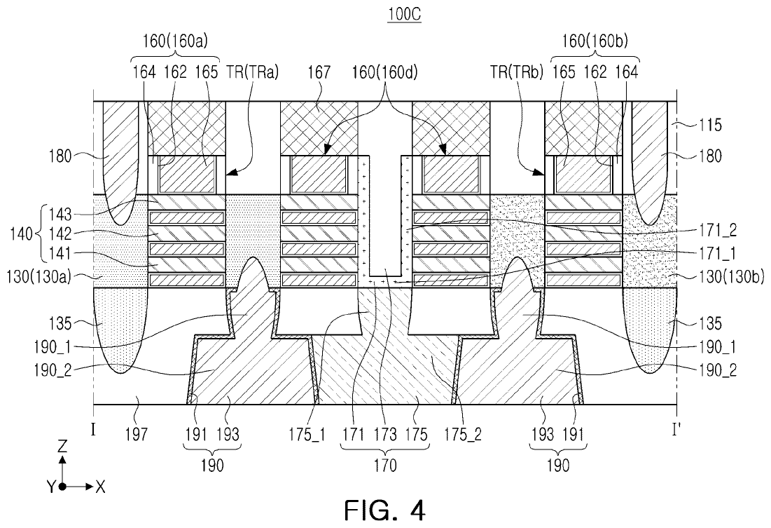

Referring to FIG. 4, differently from the semiconductor device 100 in FIG. 1B, in a semiconductor device 100C, the backside contact structure 190 may include an insulating barrier layer 191 and a lower conductive layer 193. The insulating barrier layer 191 may be disposed between the lower conductive layer 193 and the substrate insulating layer 197 and between the lower conductive layer 193 and the second pattern portion 175_2 of the lower insulating pattern 175. The insulating barrier layer 191 may be disposed between the lower conductive layer 193 and the source/drain region 130 below the source/drain region 130 to which the backside contact structure 190 is connected. The insulating barrier layer 191 may include an insulating material, for example, a silicon nitride such as SiN. The lower conductive layer 193 may include a metal material such as tungsten (W), cobalt (Co), molybdenum (Mo), copper (Cu), ruthenium (Ru), aluminum (Al), for example, a metal nitride such as titanium nitride (TiN), tantalum nitride (TaN), or tungsten nitride (WN), or a metal such as titanium (Ti), cobalt (Co), molybdenum (Mo), or platinum (Pt).

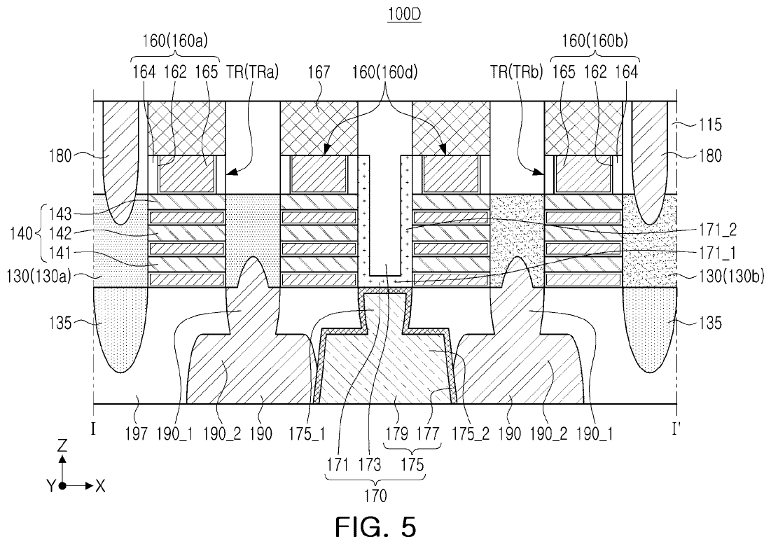

Referring to FIG. 5, differently from the semiconductor device 100 in FIG. 1B, in a semiconductor device 100d, the lower insulating pattern 175 may include a lower insulating liner 177 and a lower insulating layer 179. The lower insulating liner 177 may be disposed between the lower insulating layer 179 and the substrate insulating layer 197. The second contact portion 190_2 of the backside contact structure 190 may be in contact with the lower insulating pattern 175, and a width of the second contact portion 190_2 in the portion may decrease as the level decreases. In some implementations, the backside contact structure 190 may have a maximum width on an upper end of the portion in which the second contact portion 190_2 and the lower insulating pattern 175 are in contact with each other. The lower insulating liner 177 may have different etch selectivity from the substrate insulating layer 197. The lower insulating liner 177 may include a material different from the lower insulating layer 179. For example, the lower insulating liner 177 may include silicon nitride such as SiN, SiOCN, or SiCN, and the lower insulating layer 179 may include a low-κ material of silicon oxide series.

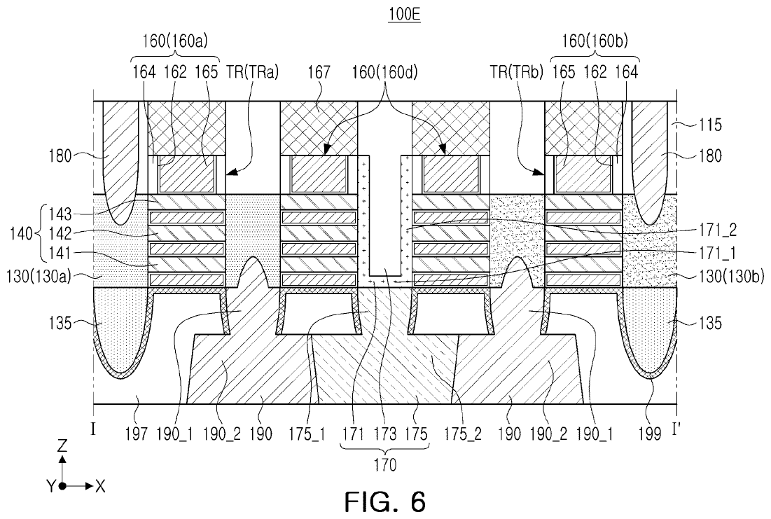

Referring to FIG. 6, differently from the semiconductor device 100 in FIG. 1B, a semiconductor device 100E may further include an intermediate insulating liner 199 covering an upper surface of the substrate insulating layer 197. The intermediate insulating liner 199 may further cover a side surface of the molding layer 135, a first pattern portion 175_1 of the lower insulating pattern 175, and a side surface of the first contact portion 190_1 of the backside contact structure 190. The intermediate insulating liner 199 may include an insulating material, for example, silicon nitride such as SiN, SiOCN, or SiCN.

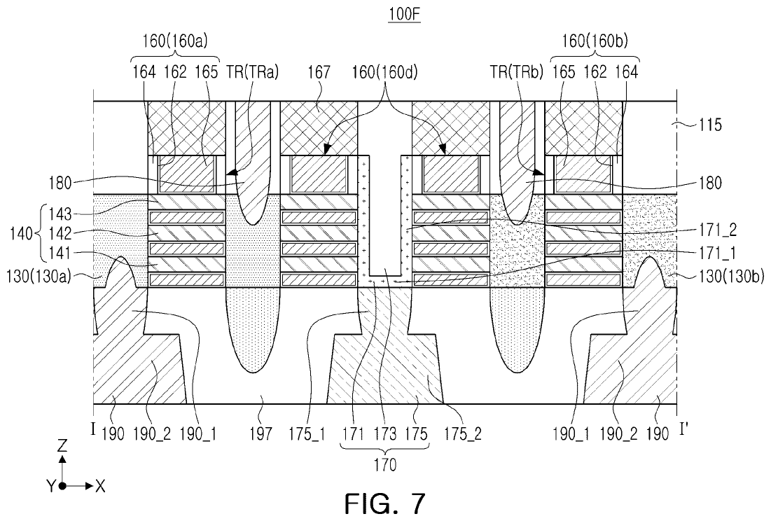

Referring to FIG. 7, differently from the semiconductor device 100 in FIG. 1B, a semiconductor device 100F may have a front-side contact structure 180 connected to a source/drain region 130 adjacent to the insulating structure 170. The backside contact structure 190 may be connected to the source/drain region 130 further spaced apart from the insulating structure 170 rather than the source/drain region 130 connected to the front-side contact structure 180.

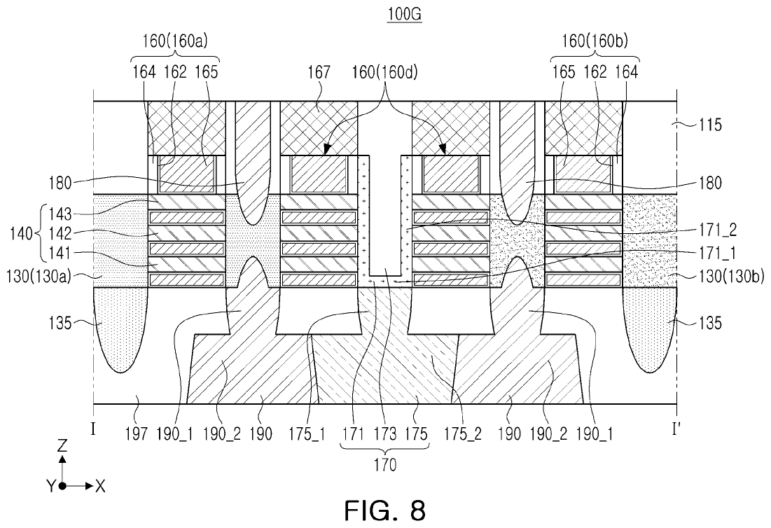

Referring to FIG. 8, differently from the semiconductor device 100 in FIG. 1B, in a semiconductor device 100G, a front-side contact structure 180 and a backside contact structure 190 may be connected to a source/drain region 130. When upper and lower portions of the semiconductor device 100G require electrical signal or heat transfer, a structure such as the semiconductor device 100G in FIG. 8 may be included.

The example implementations in FIG. 1B and FIGS. 2 to 8 may be combined variously in a compatible range.

FIGS. 9A, 9B, 9C, 9D, 9E, 9F, 9G, 9H, 9I, 9J, 9K, 9L, 9M, 9N, 9O, 9P, 9Q, 9R, 9S, and 9T are cross-sectional diagrams illustrating processes of an example of a method of manufacturing a semiconductor device in order, illustrating a region corresponding to FIG. 1B and illustrating a method of manufacturing the semiconductor device 100 in FIG. 1B.

Referring to FIG. 9A, a plurality of sacrificial layers 120 and a plurality of channel layers 141, 142, and 143 may be alternately stacked on a substrate 101.

The substrate 101 may include silicon (Si), germanium (Ge), or silicon germanium (SiGe). The substrate 101 may include a bulk wafer, an epitaxial layer, a silicon on insulator (SOI) layer, or a semiconductor on insulator (SeOI) layer.

The plurality of channel layers 141, 142, and 143 may include the first to third channel layers 141, 142, and 143. The plurality of sacrificial layers 120 may be replaced with gate dielectric layers 162 and gate electrodes 165 disposed below the first to third channel layers 141, 142, and 143 through a subsequent process as in FIG. 1B. The plurality of sacrificial layers 120 may be formed of a material having etch selectivity with respect to each of the first to third channel layers 141, 142, and 143. The first to third channel layers 141, 142, and 143 may include a material different from that of the plurality of sacrificial layers 120. The plurality of sacrificial layers 120 and the first to third channel layers 141, 142, and 143 may include a semiconductor material including at least one of, for example, silicon (Si), silicon germanium (SiGe), and germanium (Ge), may include different materials, and may or may not include impurities. For example, the plurality of sacrificial layers 120 may include silicon germanium (SiGe), and the first to third channel layers 141, 142, and 143 may include silicon (Si). The plurality of sacrificial layers 120 and the first to third channel layers 141, 142, and 143 may be formed by performing an epitaxial growth process from the stack structure. The number of channel layers stacked alternately with the sacrificial layers 120 may be varied in some implementations.

Although not specifically illustrated, by partially removing the plurality of sacrificial layers 120, the first to third channel layers 141, 142, and 143, and the substrate 101, an active structure including an active region may be formed, and a device isolation layer may be further formed.

Referring to FIG. 9B, sacrificial gate structures 200 may be formed on the active structure.

Each of the sacrificial gate structures 200 may be a sacrificial structure formed in a region in which the gate dielectric layers 162 and the gate electrode 165 are disposed on the channel structure 140 as in FIG. 1B through a subsequent process. The sacrificial gate structures 200 may have a line shape extending in one direction intersecting the active structure. The sacrificial gate structures 200 may extend in the Y-direction, for example. Each of the sacrificial gate structures 200 may include first and second sacrificial gate layers 202 and 205 and a mask pattern layer 206 stacked in order. The first and second sacrificial gate layers 202 and 205 may be patterned using the mask pattern layer 206.

Each of the first and second sacrificial gate layers 202 and 205 may be an insulating layer and a conductive layer, respectively, but an example implementation thereof is not limited thereto, and the first and second sacrificial gate layers 202 and 205 may be formed as an integrated layer. For example, the first sacrificial gate layer 202 may include silicon oxide, and the second sacrificial gate layer 205 may include polysilicon. The mask pattern layer 206 may include silicon oxide and/or silicon nitride.

Referring to FIG. 9C, a gate spacer layer 164 covering the active structure and the sacrificial gate structure 200 may be formed.

The gate spacer layer 164 may be formed by depositing an insulating material on the active structure and the sacrificial gate structure 200. The gate spacer layers 164 may be formed of a low-κ material, and may include, for example, at least one of SiO, SiN, SiCN, SiOC, SiON, and SiOCN.

Referring to FIG. 9D, by performing an etching process using the sacrificial gate structures 200 as an etching mask, recess regions RC penetrating the active structure and exposing the active region may be formed.

A portion of the exposed sacrificial layers 120 and a portion of the first to third channel layers 141, 142, and 143 may be removed using the sacrificial gate structures 200 and the gate spacer layers 164 as a mask, thereby forming the recess regions RC. Accordingly, the first to third channel layers 141, 142, and 143 may form channel structures 140 having a limited length in the X-direction.

The specific shape of a side surface of the sacrificial layers 120 is not limited to the example illustrated in FIG. 9D. In some implementations, the sacrificial layers 120 may be selectively etched with respect to the channel structures 140 by, for example, a wet etching process, and may be removed from the side surface in the X-direction to a predetermined depth. In this case, differently from the illustrated example, the sacrificial layers 120 may have inwardly curved side surfaces by etching the side surface as described above.

Referring to FIG. 9E, by further etching the substrate 101 including the active region, the recess regions RC may extend.

This process may be performed simultaneously with or separately from the process in FIG. 9D. The substrate 101 may be further etched using the sacrificial gate structures 200 and the gate spacer layers 164 as masks, and the recess regions RC may extend.

Referring to FIG. 9F, a molding layer 135 partially filling the recess regions RC below the sacrificial layer 120 may be formed.

The molding layer 135 may partially fill the recess regions RC from below. The molding layer 135 may be formed by growing, for example, a selective epitaxial process. The molding layer 135 may include silicon germanium (SiGe), and an upper surface of the molding layer 135 may partially fill the recess regions RC below a lower surface of the first channel layer 141.

Referring to FIG. 9G, an upper insulating liner 171 may be formed.

The upper insulating liner 171 may cover sacrificial gate structures 200, sacrificial layers 120, a plurality of channel layers 141, 142, and 143 and a molding layer 135. The upper insulating liner 171 may be formed by depositing an insulating material, for example, silicon nitride such as SiN, SiOCN, SiCN, or the like. The upper insulating liner 171 may conformally cover the sacrificial gate structures 200, the sacrificial layers 120, the plurality of channel layers 141, 142, and 143 and the molding layer 135.

Referring to FIG. 9H, the first mask pattern MP1 may be formed, the upper insulating liner 171 may be partially removed, and the first source/drain regions 130a may be formed.

The first mask pattern MP1 may be formed to expose a space for forming the first transistor TRa in FIG. 1B. The upper insulating liner 171 exposed by the first mask pattern MP1 may be removed, and the first source/drain regions 130a filling the recess region RC may be formed. The first source/drain regions 130a may be formed by growing, for example, by a selective epitaxial process. Each of the first source/drain regions 130a may include a plurality of epitaxial layers having different compositions.

Referring to FIG. 9I, the first mask pattern MP1 may be removed, the second mask pattern MP2 may be formed, a portion of the upper insulating liner 171 may be partially removed, and the second source/drain regions 130b may be formed.

The first mask pattern MP1 exposing a space for forming the first transistor TRa may be removed, and the second mask pattern MP2 exposing a space for forming the second transistor TRb may be formed. The first region in which the first mask pattern MP1 is formed and the second region in which the second mask pattern MP2 is formed may overlap each other in a region of overlap in which the upper insulating liner 171 and the upper insulating layer 173 in FIG. 1B are formed. Accordingly, after removing a portion of the upper insulating liner 171 exposed by the second mask pattern MP2, the upper insulating liner 171 may remain in the region of overlap. The upper insulating liner 171 exposed by the second mask pattern MP2 may be removed, and second source/drain regions 130b filling the recess region RC may be formed. The second source/drain regions 130b may be formed by, for example, growing by a selective epitaxial process. Each of the second source/drain regions 130b may include a plurality of epitaxial layers having different compositions. The first source/drain regions 130a and the second source/drain regions 130b may have different conductivity types. In some implementations, the second source/drain regions 130b may be formed preferentially, and the first source/drain regions 130a may be formed.

By this process, transistors of different conductivity types, adjacently disposed, may be formed without an additional process of cutting and separating the active structure, thereby reducing process costs and process difficulty, and a semiconductor device having improved integration density and a method of manufacturing the same may be provided.

Referring to FIG. 9J, the interlayer insulating layer 115 and the upper insulating layer 173 may be formed, and the sacrificial gate structures 200 and the sacrificial layers 120 may be removed.

The interlayer insulating layer 115 and the upper insulating layer 173 may be formed by forming an insulating film covering the sacrificial gate structures 200 and the source/drain regions 130 and performing a planarization process. In some implementations, the upper insulating layer 173 may be formed of the same material as the upper insulating liner 171 by using an additional mask.

The sacrificial gate structures 200 and the sacrificial layers 120 may be selectively removed with respect to the gate spacer layers 164, the interlayer insulating layer 115, and the channel structures 140. First, the upper gap regions UR may be formed by removing the sacrificial gate structures 200, and the lower gap regions LR may be formed by removing the sacrificial layers 120 exposed through the upper gap regions UR.

Referring to FIG. 9K, by forming gate dielectric layers 162 and gate electrode 165, gate structures 160 may be formed.

The gate dielectric layers 162 and the gate electrode 165 may be formed to fill the upper gap regions UR and the lower gap regions LR. The gate dielectric layers 162 may be formed to conformally cover internal surfaces of the upper gap regions UR and the lower gap regions LR. The gate electrode 165 may be formed to completely fill the upper gap regions UR and the lower gap regions LR, and may be removed from an upper portion of the upper gap regions UR to a predetermined depth together with the gate dielectric layers 162 and the gate spacer layers 164. Thereafter, a gate capping layer 167 may be further formed on the gate structures 160.

Referring to FIG. 9L, a front-side contact structure 180 penetrating the interlayer insulating layer 115 and connected to the source/drain region 130 may be formed.

The front-side contact structure 180 may be formed by forming a hole penetrating the interlayer insulating layer 115 by partially etching the source/drain region 130 from an upper portion, and filling the hole with a conductive material. In some implementations, a metal-semiconductor compound layer may be formed on the source/drain region 130 exposed by the hole, and a front-side contact structure 180 including the metal-semiconductor compound layer may be formed. Although not specifically illustrated, metal interconnections and an upper insulating layer covering the metal interconnections may be formed on an upper portion of the front-side contact structure 180, a gate contact connected to the gate electrode 165 of the first gate structure 160a and the second gate structure 160b may be formed.

Referring to FIG. 9M, the entire structure formed with reference to FIGS. 9A to 9L may be attached to a carrier substrate, and the substrate 101 and the device isolation layer may be removed. In the drawings in FIG. 9M and following drawings, the entire structure may be rotated or inversed in a form of a mirror image of the structure illustrated in FIG. 9L for ease of description.

The substrate 101 may be removed from an upper surface of the substrate 101. The substrate 101 may be removed, for example, by a lapping, grinding, or polishing process, and may be thinned, and the remaining region may be removed by an etching and/or oxidation process. However, the removed thickness of the substrate 101 may be varied in some implementations. The substrate 101 may be removed by an additional wet etching process, or the like. In some implementations, the substrate 101 may not be completely removed and may remain partially. In this case, an active region may remain on an uppermost surface of the gate structures 160.

Referring to FIG. 9N, a substrate insulating layer 197 may be formed in the region from which the substrate 101 is removed.

The substrate insulating layer 197 may be formed in the region from which the substrate 101 is removed. The substrate insulating layer 197 may cover the molding layer 135 and the gate structure 160 which may be exposed as the substrate 101 is removed. When a portion of the device isolation layer remains without being removed together with the substrate 101, the substrate insulating layer 197 may include the remaining device isolation layer.

Referring to FIG. 9O, a back-surface hole BH exposing the molding layer 135 in contact with the upper insulating liner 171 may be formed.

The back-surface hole BH may be formed by selectively etching the substrate insulating layer 197 such that the molding layer 135 on the upper insulating liner 171 may be exposed. The back-surface hole BH may be formed by, for example, dry etching or wet etching. Depending on etch selectivity, the molding layer 135 may be etched less than the substrate insulating layer 197 or may be etched.

Referring to FIG. 9P, the molding layer 135 exposed by the back-surface hole BH may be removed.

The molding layer 135 may be selectively removed, and the upper insulating liner 171 may be exposed on the back-surface hole BH. Since the upper insulating liner 171 includes a different material having etch selectivity with respect to the molding layer 135, the upper insulating liner 171 may not be removed when the molding layer 135 is removed.

Referring to FIG. 9Q, the insulating structure 170 may be formed by forming a lower insulating pattern 175 filling the back-surface hole BH.

The lower insulating pattern 175 may be formed by filling the back-surface hole BH with a flowable low-k material, or the like. The first pattern portion 175_1 of the lower insulating pattern 175 may have a side shape according to the shape of the molding layer 135.

Referring to FIG. 9R, a contact hole CTH exposing a portion of the molding layer 135 may be formed.

The contact hole CTH may be formed in a region in which the backside contact structure 190 in FIG. 1B is disposed. The contact hole CTH may expose the molding layer 135 on the source/drain region 130. Depending on the etching method and the width of the contact hole CTH, a portion of the lower insulating pattern 175 may be removed together.

Referring to FIG. 9S, the molding layer 135 exposed by the contact hole CTH may be removed.

The molding layer 135 may be selectively removed, and the source/drain regions 130 may be exposed on the contact hole CTH. The source/drain regions 130 may have a composition of a material different from that of the molding layer 135, such that the source/drain regions 130 may not be removed when the molding layer 135 is removed. For example, the source/drain regions 130 may not include germanium (Ge) or may include germanium (Ge) in a concentration lower than that of the molding layer 135, and the molding layer 135 may include germanium (Ge) in a concentration higher than that of the source/drain regions 130, and accordingly, the source/drain regions 130 may have an etch selectivity with respect to the molding layer 135.

Referring to FIG. 9T, the contact hole CTH may extend by removing a portion of the exposed source/drain region 130.

Referring to FIG. 1B together, the source/drain region 130 may be partially removed from an upper portion, and a backside contact structure 190 may be formed by filling a conductive material in the contact hole CTH. In some implementations, a metal-semiconductor compound layer may be formed on the source/drain region 130 exposed by the contact hole CTH, and a backside contact structure 190 including the metal-semiconductor compound layer may be formed. Accordingly, the semiconductor device 100 in FIG. 1B may be manufactured.

In the description of a method of manufacturing a semiconductor device below, descriptions overlapping the descriptions with respect to FIGS. 9A to 9T will not be provided.

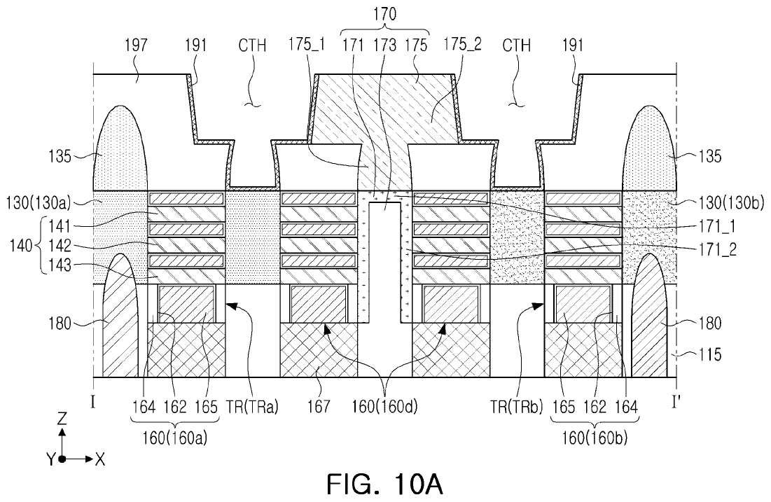

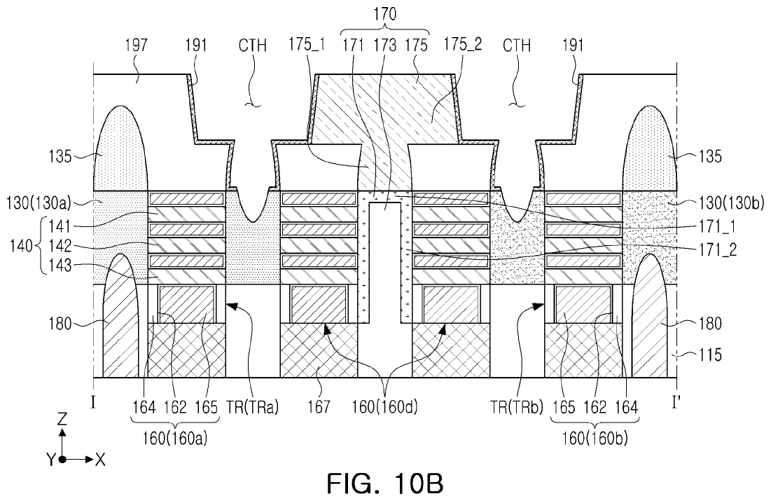

FIGS. 10A and 10B are cross-sectional diagrams illustrating processes of an example of a method of manufacturing a semiconductor device in order. FIGS. 10A and 10B illustrate regions corresponding to FIG. 4 and illustrate a method of manufacturing the semiconductor device 100C in FIG. 4.

Referring to FIG. 10A, after the process in FIG. 9S, an insulating barrier layer 191 may be formed in the contact hole CTH.

The insulating barrier layer 191 may be formed by depositing an insulating material such as silicon nitride in the contact hole CTH. By forming the insulating barrier layer 191, the peripheral components may be protected in the subsequent process.

Referring to FIG. 10B, the contact hole CTH may be expanded to penetrate the insulating barrier layer 191 and to extend into the source/drain region 130.

This process may be performed, for example, by dry etching. Referring to FIG. 4 together, by filling a conductive material in the contact hole CTH, a backside contact structure 190 including an insulating barrier layer 191 and a lower conductive layer 193 may be formed, and the semiconductor device 100C in FIG. 4 may be manufactured.

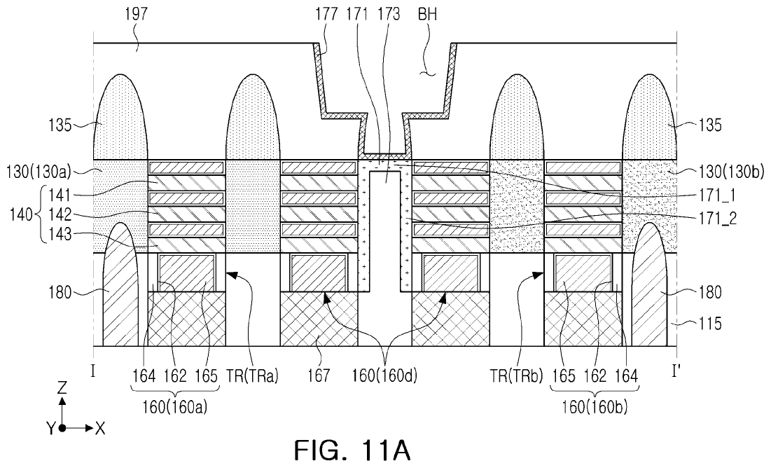

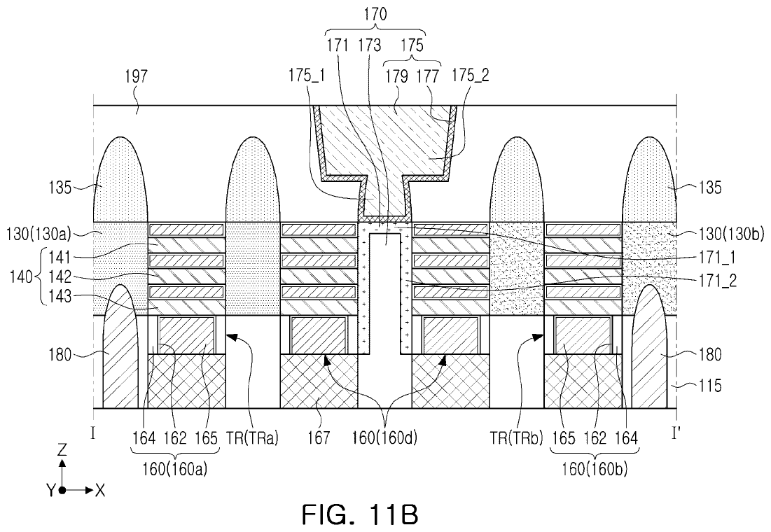

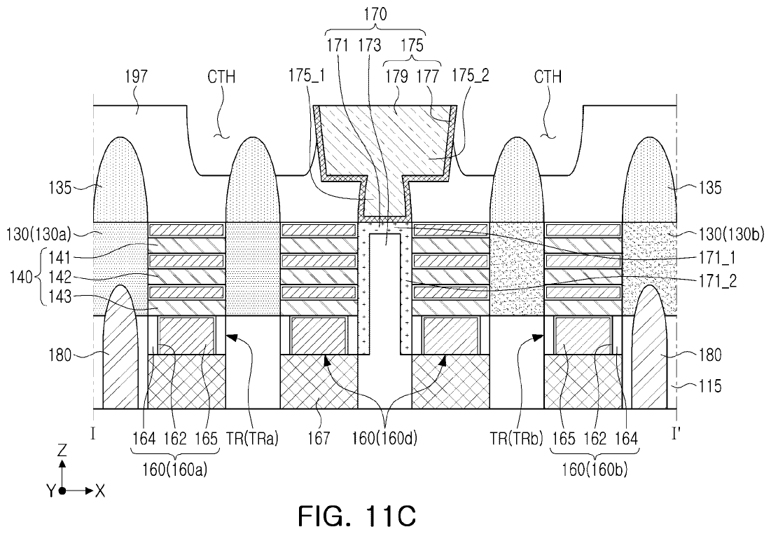

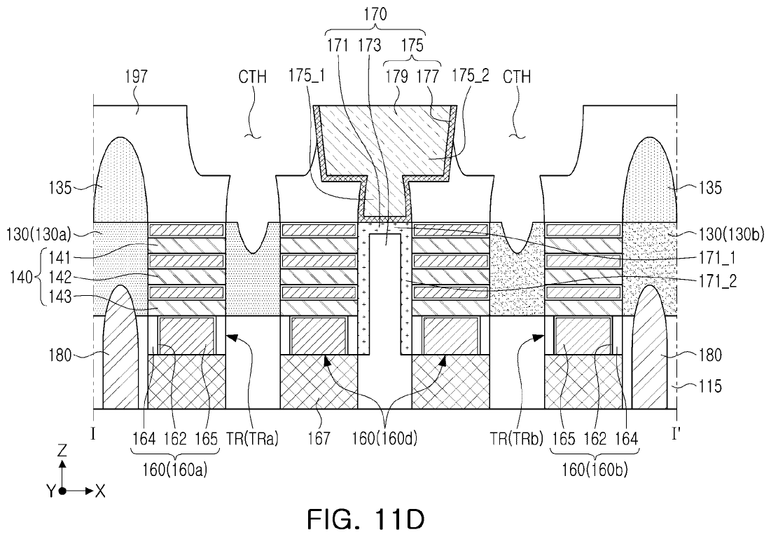

FIGS. 11A, 11B, 11C, and 11D are cross-sectional diagrams illustrating processes of an example of a method of manufacturing a semiconductor device in order. FIGS. 11A to 11D illustrate a region corresponding to FIG. 5 and illustrate a method of manufacturing the semiconductor device 100d in FIG. 5.

Referring to FIG. 11A, after the process in FIG. 9P, a lower insulating liner 177 may be formed in a back-surface hole BH.

The lower insulating liner 177 may be formed by depositing an insulating material such as silicon nitride in the back-surface hole BH. The lower insulating liner 177 may conformally cover the upper insulating liner 171 and the substrate insulating layer 197 exposed by the back-surface hole BH.

Referring to FIG. 11B, the lower insulating layer 179 filling the back-surface hole BH may be formed, thereby forming the lower insulating pattern 175.

The lower insulating layer 179 may include a different material from that of the lower insulating liner 177. For example, the lower insulating layer 179 may include a low-κ material such as silicon oxide series. The lower insulating liner 177 may have a higher etch selectivity with respect to the substrate insulating layer 197 than the lower insulating layer 179.

Referring to FIG. 11C, a contact hole CTH exposing the molding layer 135 adjacent to the lower insulating pattern 175 may be formed by partially removing the substrate insulating layer 197.

The substrate insulating layer 197 may be etched, for example, by wet etching, and the lower insulating liner 177 may have etch selectivity different from that of the substrate insulating layer 197, and thus, the substrate insulating layer 197 may be selectively etched without etching the lower insulating pattern 175.

Referring to FIG. 11D, the source/drain region 130 may be exposed by removing the molding layer 135 exposed by the contact hole CTH, and the source/drain region 130 may be partially removed from an upper portion.

The contact hole CTH may be expanded by removing the molding layer 135 and partially removing the source/drain region 130. Referring to FIG. 5 together, by filling a conductive material in the contact hole CTH, a backside contact structure 190 may be formed.

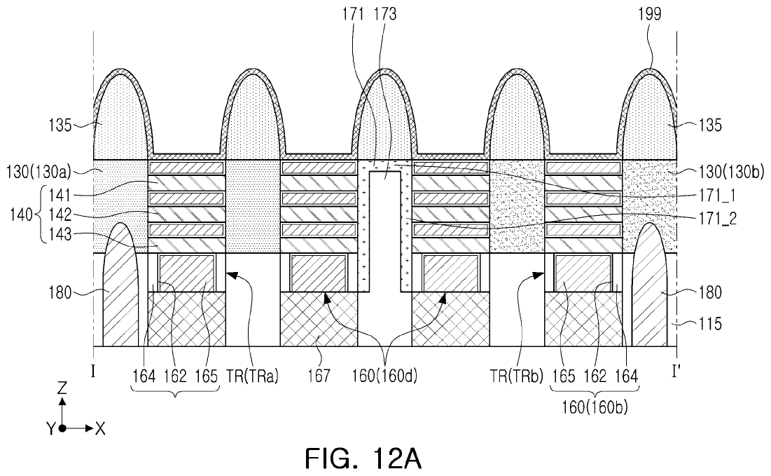

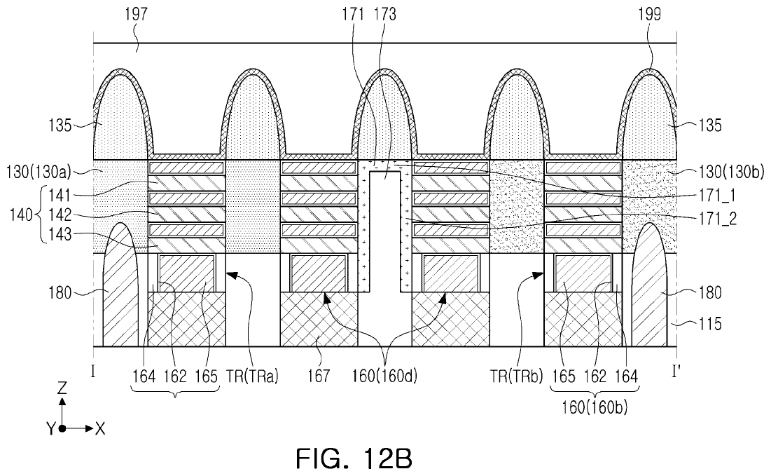

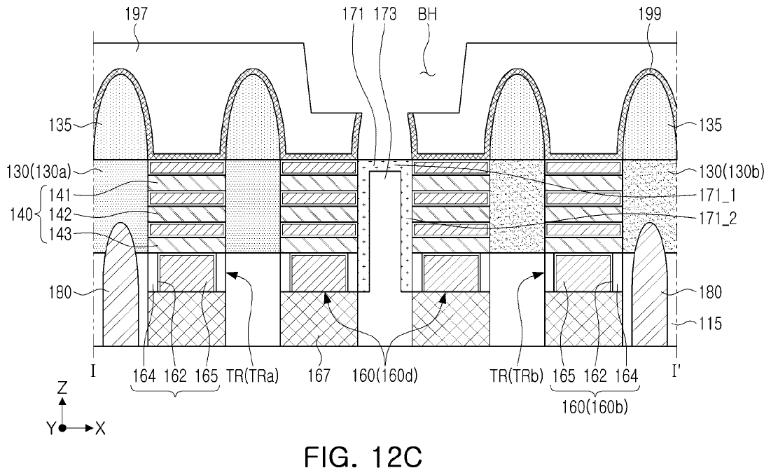

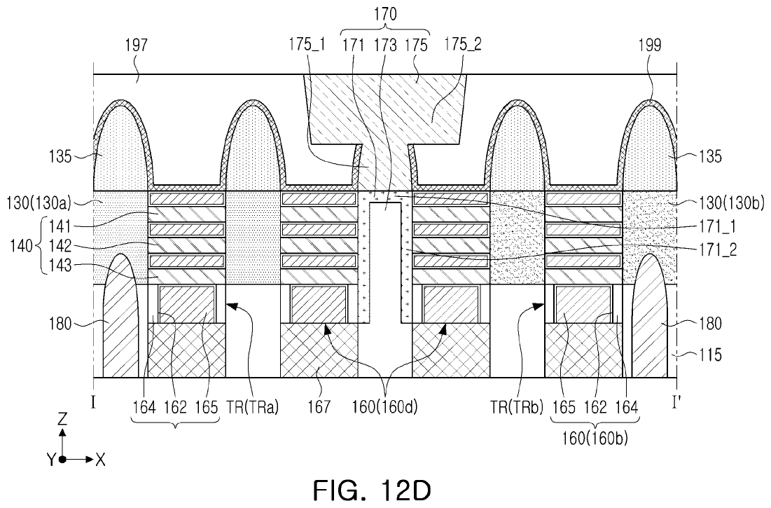

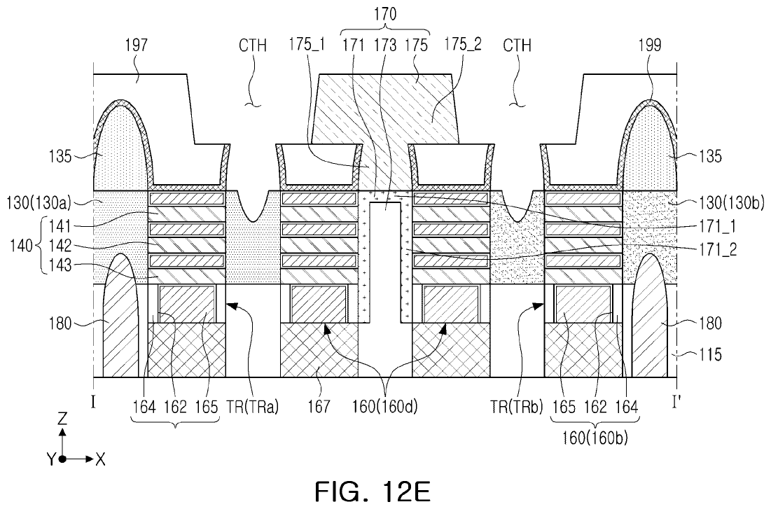

FIGS. 12A, 12B, 12C, 12D, and 12E are cross-sectional diagrams illustrating processes of an example of a method of manufacturing a semiconductor device in order. FIGS. 12A to 12E illustrate a region corresponding to FIG. 6, and illustrate a method of manufacturing the semiconductor device 100E in FIG. 6.

Referring to FIG. 12A, after the process in FIG. 9M, an intermediate insulating liner 199 covering an upper surface of the exposed molding layer 135 and the gate structure 160 may be formed.

The intermediate insulating liner 199 may be formed by depositing an insulating material such as silicon nitride. The intermediate insulating liner 199 may conformally cover the molding layer 135 and the gate structure 160.

Referring to FIG. 12B, a substrate insulating layer 197 may be formed on the intermediate insulating liner 199.

The substrate insulating layer 197 may be formed on the intermediate insulating liner 199 using an insulating material different from that of the intermediate insulating liner 199. For example, the intermediate insulating liner 199 may include silicon nitride, and the substrate insulating layer 197 may include silicon oxide.

Referring to FIG. 12C, a back-surface hole BH removing the molding layer 135 on the upper insulating liner 171 may be formed.

A portion covering the molding layer 135 on the upper insulating liner 171 of the intermediate insulating liner 199 may be partially removed by a back-surface hole BH, and a back-surface hole BH exposing the upper insulating liner 171 may be formed by removing the exposed molding layer 135.

Referring to FIG. 12D, a lower insulating pattern 175 filling the back-surface hole BH may be formed.

The lower insulating pattern 175 may be formed by filling a low-κ material such as a silicon oxide series in the back-surface hole BH. A side surface of the first pattern portion 175_1 of the lower insulating pattern 175 may be in contact with the intermediate insulating liner 199 portion formed on a side surface of the molding layer 135.

Referring to FIG. 12E, a portion of the substrate insulating layer 197 and the intermediate insulating liner 199 may be removed, and a molding layer 135 may be removed, thereby forming a contact hole CTH.

In some implementations, the molding layer 135 may be exposed by removing a portion of the substrate insulating layer 197 and the intermediate insulating liner 199 by a method such as dry etching, and the source/drain region 130 may be exposed by selectively removing the exposed molding layer 135 by a method such as wet etching. Referring to FIG. 6 together, a portion of the exposed source/drain region 130 may be removed from an upper portion, and a conductive material may be filled in the contact hole CTH such that a backside contact structure 190 may be formed.

According to the aforementioned example implementations, by including an insulating structure including an upper insulating liner and a lower insulating pattern disposed between transistors having different conductivity types, a semiconductor device having improved reliability and integration density may be provided.

Also, by including an insulating structure including an upper insulating liner and a lower insulating pattern disposed between transistors having different conductivity types, a method of manufacturing a semiconductor device having improved reliability and integration density may be provided.

In general, according to some aspects, a method of manufacturing a semiconductor device includes preparing an active structure in which a plurality of sacrificial layers and a plurality of channel layers are alternately stacked on a substrate; forming sacrificial gate structures extending by intersecting the active structure on the active structure; forming recess regions by removing a portion of the active structure exposed from the sacrificial gate structures; forming an upper insulating liner covering the sacrificial gate structures and the active structure; forming a first mask pattern covering a portion of the recess regions; removing a portion of an upper insulating liner of a region exposed by the first mask pattern; forming first source/drain regions having a first conductivity-type in the recess regions of a region exposed by the first mask pattern; removing the first mask pattern; forming a second mask pattern covering the first source/drain regions, wherein the first mask pattern and the second mask pattern have a region of overlap, and the region of overlap includes at least one of the recess regions; partially removing the upper insulating liner of a region exposed by the second mask pattern; forming second source/drain regions of a second conductivity-type different from the first conductivity-type in the recess regions of a region exposed by the second mask pattern; removing the second mask pattern; removing the sacrificial gate structures and the plurality of sacrificial layers and forming a gate structure; removing the substrate and forming a substrate insulating layer; and forming a lower insulating pattern penetrating the substrate insulating layer and in contact with the upper insulating liner, wherein the lower insulating pattern may include a material having a dielectric constant different from a dielectric constant of the substrate insulating layer.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the example implementations have been illustrated and described above, it will be configured as apparent to those skilled in the art that modifications and variations could be made without departing from the scope of the present disclosure as defined by the appended claims.

What is claimed is:

1. A semiconductor device comprising:
a substrate insulating layer;
an insulating structure extending through the substrate insulating layer;
a first transistor on a first side of the insulating structure, the first transistor including a first gate structure and first source/drain regions, the first gate structure extending in a first direction on the substrate insulating layer, and the first source/drain regions having a first conductivity-type on both a first side of the first gate structure and a second side of the first gate structure;
a second transistor on a second side of the insulating structure that is opposite to the first side of the insulating structure, the second transistor including a second gate structure and second source/drain regions, the second gate structure extending in the first direction on the substrate insulating layer, and the second source/drain regions having a second conductivity-type different from the first conductivity-type on both a first side of the second gate structure and a second side of the second gate structure; and
a plurality of dummy gate structures between the first transistor and the insulating structure and between the second transistor and the insulating structure,
wherein the insulating structure includes:
a lower insulating pattern extending through the substrate insulating layer; and
an upper insulating liner covering at least a portion of a first side surface of the dummy gate structures and a second side surface of the dummy gate structures, the first side surface of the dummy gate structures being opposite to the second side surface of the dummy gate structures, and
wherein the lower insulating pattern includes a material having a first dielectric constant that is different from a second dielectric constant of the substrate insulating layer.

2. The semiconductor device of claim 1, wherein the first dielectric constant is lower than the second dielectric constant.

3. The semiconductor device of claim 1,
wherein the first transistor and the second transistor are spaced apart from each other in a second direction, and
wherein a cross-sectional surface in the second direction of the upper insulating liner has a “U” shape.

4. The semiconductor device of claim 1, wherein the upper insulating liner includes a material different from the material of the lower insulating pattern.

5. The semiconductor device of claim 1,
wherein the insulating structure includes an upper insulating layer on the upper insulating liner, and
wherein the upper insulating layer includes a material different from a material of the upper insulating liner.

6. The semiconductor device of claim 5,
wherein the upper insulating layer includes silicon oxide, and
wherein the upper insulating liner includes silicon nitride.

7. The semiconductor device of claim 1,
wherein the first transistor includes a first backside contact structure extending through the substrate insulating layer and connected with a first source/drain region disposed adjacent to the insulating structure among the first source/drain regions, and
wherein the second transistor includes a second backside contact structure extending through the substrate insulating layer and connected with a second source/drain region disposed adjacent to the insulating structure among the second source/drain regions.

8. The semiconductor device of claim 7, wherein the first backside contact structure and the second backside contact structure contact the lower insulating pattern.

9. The semiconductor device of claim 7,
wherein the first transistor includes a first front-side contact structure connected with a first source/drain region disconnected with the first backside contact structure among the first source/drain regions, and
wherein the second transistor includes a second front-side contact structure connected with a second source/drain region disconnected with the second backside contact structure among the second source/drain regions.

10. The semiconductor device of claim 7,
wherein the lower insulating pattern includes a lower insulating layer and a lower insulating liner disposed between the lower insulating layer and the substrate insulating layer, and
wherein the lower insulating liner includes a material different from a material of the lower insulating layer.

11. The semiconductor device of claim 10,
wherein the lower insulating liner includes silicon nitride, and
wherein the lower insulating layer includes silicon carbon oxide.

12. The semiconductor device of claim 1,
wherein the first conductivity-type is P-type, and
wherein the second conductivity-type is N-type.

13. A semiconductor device comprising:
a substrate insulating layer;
a plurality of gate structures spaced apart from each other in a first direction on the substrate insulating layer, the plurality of gate structures extending in a second direction intersecting the first direction;
a plurality of channel layers surrounded by the plurality of gate structures on the substrate insulating layer, respectively;
an upper insulating liner covering a first side surface of the plurality of gate structures and a second side surface of the plurality of gate structures, the first side surface of the plurality of gate structures being opposite to the second side surface of the plurality of gate structures;
a lower insulating pattern extending through the substrate insulating layer and contacting the upper insulating liner;
source/drain regions on an external side of the plurality of gate structures and connected with the plurality of channel layers; and
a plurality of backside contact structures extending through the substrate insulating layer and connected with the source/drain regions,
wherein the upper insulating liner includes a lower portion contacting the substrate insulating layer and the lower insulating pattern, and a first side portion and a second side portion extending along the first side surface and the second side surface of the plurality of gate structures, respectively.

14. The semiconductor device of claim 13, wherein the first side portion and the second side portion contact at least a portion of the plurality of channel layers.

15. The semiconductor device of claim 13, wherein upper ends of the first side portion and the second side portion are at a same level as an upper surface of the plurality of gate structures.

16. The semiconductor device of claim 13, comprising:
an interlayer insulating layer covering at least a portion of each gate structure of the plurality of gate structures and the source/drain regions, and the interlayer insulating layer filling a region between the first side portion and the second side portion on the lower portion of the upper insulating liner.

17. The semiconductor device of claim 16, wherein the upper insulating liner includes a material different from a material of the interlayer insulating layer.

18. A semiconductor device comprising:
a substrate insulating layer;
a plurality of gate structures spaced apart from each other in a first direction on the substrate insulating layer, the plurality of gate structures extending in a second direction intersecting the first direction, wherein the plurality of gate structures include a first gate structure, a second gate structure, and a plurality of dummy gate structures between the first gate structure and the second gate structure;
first source/drain regions on both a first side of the first gate structure and a second side of the first gate structure;
second source/drain regions on both a first side of the second gate structure and a second side of the second gate structure; and
an insulating structure between the plurality of dummy gate structures,
wherein the insulating structure includes:
an upper insulating layer between the plurality of dummy gate structures on the substrate insulating layer;
an insulating liner extending in the second direction between the upper insulating layer and the plurality of dummy gate structures; and
a lower insulating pattern extending through the substrate insulating layer and contacting the insulating liner.

19. The semiconductor device of claim 18, wherein the lower insulating pattern includes a material different from a material of the insulating liner.

20. The semiconductor device of claim 18,
wherein the first source/drain regions have a first conductivity-type, and
wherein the second source/drain regions have a second conductivity-type different from the first conductivity-type.
